(19) United States
(12) Patent Application Publication
(10) Pub. No.: US 2007/0111461 A1
(43) Pub. Date: May 17, 2007

(54) Systems And Methods For Forming Integrated Circuit Components Having Matching Geometries

(76) Inventor: Kent G. Green, Pflugerville, TX (US)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/622,735

(22) Filed: Jan. 12, 2007

Related U.S. Application Data
(63) Continuation of application No. PCT/US05/24957, filed on Jul. 14, 2005.
(60) Provisional application No. 60/588,282, filed on Jul. 15, 2004.

(51) Int. Cl. H01L 21/20

(52) U.S. Cl. 438/382

(57) ABSTRACT

In a particular embodiment, a method of forming integrated circuit components is provided. A first photomask is formed, the first photomask including a first mask component having a first geometry corresponding to a first type of integrated circuit component. A first lithography process is performed to transfer the first geometry of the first mask component of the first photomask to a first location on a first die on a semiconductor wafer to form a first integrated circuit component of the first type of integrated circuit component on the first die. A second lithography process is performed to transfer the first geometry of the first mask component of the first photomask to a second location on the first die on the semiconductor wafer to form a second integrated circuit component of the first type of integrated circuit component on the first die.

### TECHNICAL FIELD OF THE INVENTION

This invention relates in general to integrated circuit fabrication and, more particularly, to a system and method for forming integrated circuit components having matching geometries.

### BACKGROUND OF THE INVENTION

Integrated circuit devices typically include various circuit components, such as various transistors, resistors and capacitors, for example. Such integrated circuit components may be produced by forming particular geometries in a semiconductor wafer (e.g., a silicon wafer) using various integrated circuit fabrication techniques, such as various deposition and lithography techniques, for example. In some instances, two or more electrical components of an integrated circuit device are related to each other such that one or more characteristics of the electrical components must “match” in order for the integrated circuit device to operate properly or as desired. For example, it may be necessary for a particular pair of resistors in an integrated circuit device to provide an equal amount of resistance in order for the device to operate properly. As another example, it may be necessary for a particular pair of capacitors in an integrated circuit device to provide an equal amount of capacitance in order for the device to operate properly or as desired.

In order to provide such components having “matching” electrical characteristics, attempts have been made to form components having identical geometries in the semiconductor wafer. However, various factors often cause imperfections and inconsistencies in the geometries of integrated circuit components formed in a semiconductor wafer, including imperfections in the geometries formed in a photomask used in the formation of the integrated circuit components, imperfections associated with the lithographic imaging of the integrated circuit components, imperfections associated with the lens used for the lithographic imaging process, and/or imperfections caused by the reflection of light during the lithographic imaging process, for example.

If it is determined that a pair of integrated circuit components that are required to match do not in fact match, the physical geometry of one or both of the pair of components on the semiconductor wafer may be modified. Using a conventional technique, for example, “tabs” may be laser ablated to one or both of the components until the relevant characteristic or characteristics (e.g., one or more electrical characteristics) of the components are determined to match. Such manipulation of the components on the semiconductor wafer may add cycle time and manpower, which may reduce the efficiency and thus increase the costs of fabricating integrated circuit devices.

### SUMMARY OF THE INVENTION

In accordance with teachings of the present invention, disadvantages and problems associated with forming critical-geometry integrated circuit components on a wafer have been substantially reduced or eliminated. In a particular embodiment, a first lithography process is used to form a first integrated circuit component of a first type of integrated circuit component on a die and a second lithography process is used to form a second integrated circuit component of the first type of integrated circuit component on the die.

In one embodiment, a method of forming integrated circuit components is provided. A first photomask is formed, the first photomask including a first mask component having a first geometry corresponding to a first type of integrated circuit component. A first lithography process is performed to transfer the first geometry of the first mask component of the first photomask to a first location on a first die on a semiconductor wafer to form a first integrated circuit component of the first type of integrated circuit component on the first die. A second lithography process is performed to transfer the first geometry of the first mask component of the first photomask to a second location on the first die on the semiconductor wafer to form a second integrated circuit component of the first type of integrated circuit component on the first die.

In another embodiment, an integrated circuit device is provided. The integrated circuit device includes a first integrated circuit component of a first type of integrated circuit component and a second integrated circuit component of the first type of integrated circuit component. The first integrated circuit component is located at a first location on a first die on a semiconductor wafer and is formed at least by: forming a first photomask including a first mask component having a first geometry corresponding to a first type of integrated circuit component; and performing a first lithography process to transfer the first geometry of the first mask component of the first photomask to the first location on the first die to form a first integrated circuit component. The second integrated circuit component is located at a second location on the first die on the semiconductor wafer and is formed at least by performing a second lithography process to transfer the first geometry of the first mask component of the first photomask to the second location on the first die to form a second integrated circuit component.

One advantage of the present disclosure is that systems and methods may be provided for forming critical-geometry integrated circuit components having substantially identical geometries. In particular, by using a single pattern geometry on a photomask to form multiple instances of a particular integrated circuit component onto different locations of a die, geometric differences between the individual integrated circuit components may be reduced as compared with prior techniques for forming such components. As a result, the number of repairs (such as laser ablation repairs, for example) required to correct integrated circuit components on a wafer that are found to have “non-matching,” inaccurate or otherwise undesirable geometries may be reduced or eliminated, thereby reducing cycle time, increasing throughput, and/or reducing costs.

All, some, or none of these technical advantages may be present in various embodiments of the present invention. Other technical advantages may be readily apparent to one skilled in the art from the following figures, descriptions, and claims.

### BRIEF DESCRIPTION OF THE DRAWINGS

A more complete and thorough understanding of the present embodiments and advantages thereof may be acquired by referring to the following description taken in conjunction with the accompanying drawings, in which like reference numbers indicate like features, and wherein:

FIG. 1 illustrates a top view of an example semiconductor wafer including a plurality of dies, or chips, each including one or more integrated circuits formed according to the present invention;

FIG. 2 illustrates a single die of the semiconductor wafer of FIG. 1, which includes integrated circuit components formed according to an embodiment of the present invention;

FIG. 3A illustrates a top view of an example first photomask that may be used to form multiple instances of a critical-geometry integrated circuit component in a first region of the die shown in FIG. 2 in accordance with an embodiment of the present invention;

FIG. 3B illustrates a cross-sectional view of a photomask assembly that includes the first photomask of FIG. 3A;

FIG. 4A illustrates a top view of an example second photomask that may be used to form one or more non-critical-geometry integrated circuit components in a second region of the die shown in FIG. 2, in accordance with an embodiment of the present invention;

FIG. 4B illustrates a cross-sectional view of a photomask assembly that includes the second photomask of FIG. 4A; and

FIG. 5 illustrates a flow chart of a method for forming critical-geometry integrated circuit components and non-critical-geometry integrated circuit components in the die shown in FIG. 2 using the first and second photomasks shown in FIGS. 3A-3B and 4A-4B in accordance with one embodiment of the invention.

### DETAILED DESCRIPTION OF THE INVENTION

Example embodiments of the present invention and their advantages are best understood by reference to FIGS. 1 through 5, where like numbers are used to indicate like and corresponding parts.

FIG. 1 illustrates a top view of an example semiconductor wafer 10 according to one embodiment of the invention. Semiconductor wafer 10 may include a plurality of dies, or chips, 12, each including one or more integrated circuits that include a variety of integrated circuit components. Semiconductor wafer 10 may comprise a thin, circular slice of single-crystal semiconductor material suitable for the manufacturing of semiconductor devices and/or integrated circuits. Semiconductor wafer 10 may include any suitable number of dies 12, which may be physically separated from each other after the integrated circuits have been formed in individual dies 12.

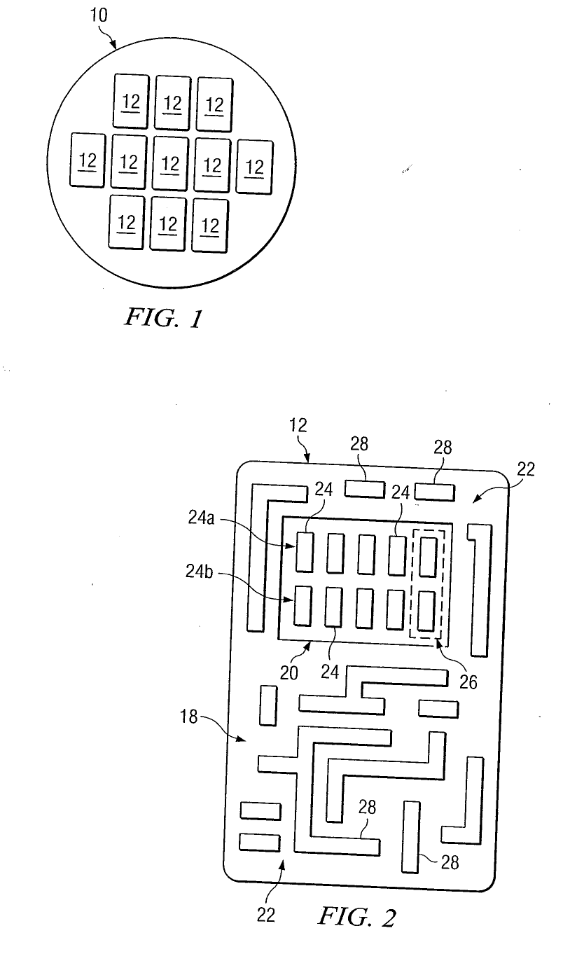

FIG. 2 illustrates a single one of dies 12 of semiconductor wafer 10, which may include integrated circuit components formed according to an embodiment of the present invention. Die 12 may include an integrated circuit 18 that includes a first region 20 and a second region 22. First region 20 may include one or more types of critical-geometry integrated circuit (IC) components 24. Critical-geometry IC components 24 may be defined as integrated circuit components for which one or more dimensions or other physical parameters, or any combination thereof, are important or critical to the proper or desired operation of the integrated circuit 18. For example, critical-geometry IC components 24 may include two or more integrated circuit components that are related to each other such that one or more electrical characteristics (or other performance characteristics) of such integrated circuit components should match each other (or should have some other particular relationship with each other). Since particular electrical characteristics of an integrated circuit component depend at least in part on the physical geometry (including shape and/or dimensions) of the integrated circuit component, the geometry of the integrated circuit component may be important or critical in order to provide the electrical characteristics required for the proper or desired operation of the integrated circuit 18. For integrated circuit components that are related to each other such that one or more electrical characteristics (or other performance characteristics) of such integrated circuit components should match each other, as discussed above, it may be important or critical that the geometries of such integrated circuit components match each other to a particular or desired degree of accuracy.

Thus, critical-geometry IC components 24 may include any integrated circuit component for which the geometries are important or critical to the operation of integrated circuit 18. For example, integrated circuit components 24 may include a pair (or more) of resistors that are related such that they should provide a substantially identical level of resistance and/or inductance in order to achieve a proper or desired operation of integrated circuit 18. As another example, integrated circuit components 24 may include a pair (or more) of capacitors that are related such that they should provide a substantially identical level of capacitance in order to achieve a proper or desired operation of integrated circuit 18.

As yet another example, integrated circuit components 24 may include a pair (or more) of inductors that are related such that they should provide a substantially identical level of inductance in order to achieve a proper or desired operation of integrated circuit 18. In the example shown in FIG. 2, the critical-geometry IC components 24 of integrated circuit 18 include five pairs of resistors that are coupled such that the resistors of each pair should provide a substantially identical level of resistance. A particular one of the five pairs of resistors is indicated by dashed line 26. It should be understood that these are merely examples, and that critical-geometry IC components 24 may include any other type(s) and/or number(s) of integrated circuit component.

Second region 22 may include one or more types of non-critical-geometry integrated circuit (IC) components 28. Non-critical-geometry IC components 28 may be defined as integrated circuit components having geometries that are generally less important or less critical than the geometries of critical-geometry IC components 24. For example, non-critical-geometry IC components 28 may include components that are not coupled to other components such that the electrical properties (or other performance characteristics) of such components need not be substantially identical for the proper or desired operation of integrated circuit 18. For example, non-critical-geometry IC components 28 may include circuit components such as resistors, capacitors, transistors, and/or inductors for which the geometries are less critical than the geometries of critical-geometry IC components 24 with respect to the proper or desired operation of integrated circuit 18. In addition, non-critical-geometry IC components 28 may include other components of an integrated circuit, such as metal lines, vias and/or other connecting structures, for example.

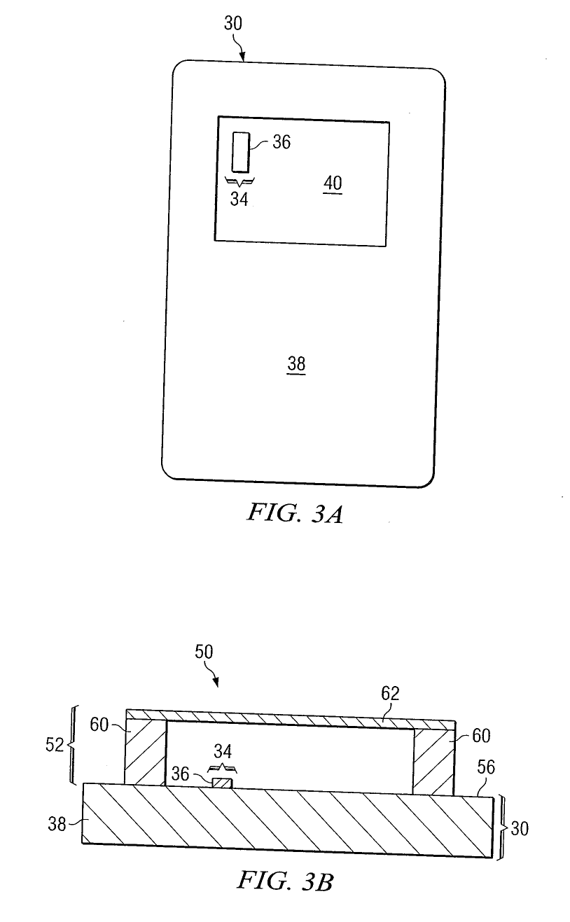

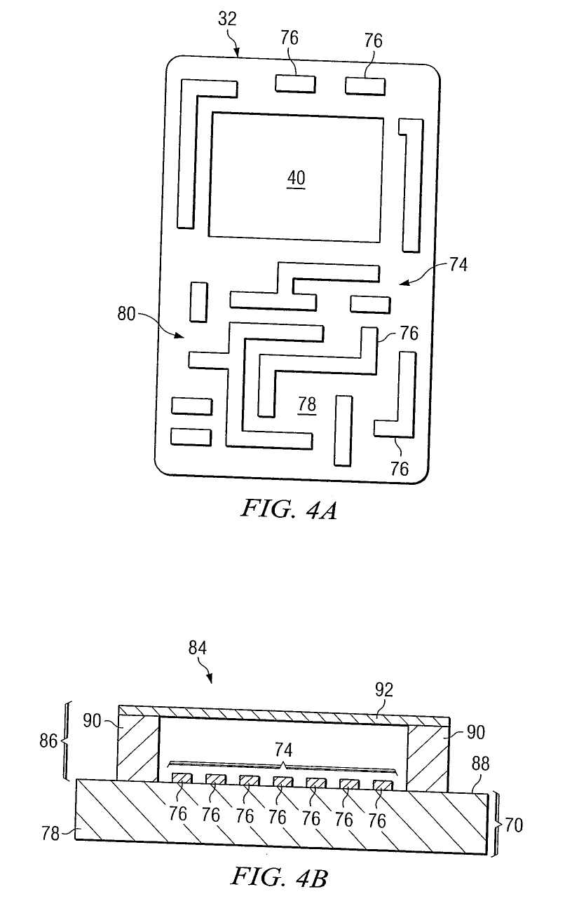

As discussed below in greater detail, critical-geometry integrated circuit components 24 may be formed in first region 20 of die 12 using a first photomask 30 (e.g., discussed below with reference to FIGS. 3A-3B), while non-critical-geometry IC components 28 may be formed in second region 22 of die 12 using a second photomask 32 (e.g., discussed below with reference to FIGS. 4A-4B). As discussed below, in certain embodiments, first photomask 30 may include a pattern that includes a single instance of a particular geometric shape and that may be used to create multiple instances of a corresponding critical-geometry integrated circuit component 24 in first region 20 by performing multiple iterations of one or more photolithographic imaging processes. Second photomask 32 may include a pattern that includes multiple instances of one or more geometric shapes and that may be used to create multiple instances of corresponding non-critical-geometry IC components 28 in a single photolithographic imaging process.

FIG. 3A illustrates a top view of an example first photomask 30 that may be used to form multiple instances of a critical-geometry integrated circuit component 24 that have substantially identical geometries in accordance with one embodiment of the invention. As discussed below, such multiple instances of a critical-geometry integrated circuit component 24 having substantially identical geometries may be formed by repeating one or more photolithographic imaging processes multiple times with first photomask 30 aligned at different positions with respect to die 12 such that a particular geometric shape in first photomask 30 may be printed onto die 12 at multiple locations of die 12.

As shown in FIG. 3A, in some embodiments, first photomask 30 may include patterned layer 34 that may include a single instance of a particular pattern geometry 36 that corresponds with a single instance of a particular type of integrated circuit component, such as a resistor or capacitor, for example. In other embodiments, patterned layer 34 may include more than one instance of a particular pattern geometry 36. In other embodiments, patterned layer 34 may include one or more instance of each of multiple pattern geometries 36 corresponds with one or more instances of one or more types of integrated circuit components. For example, in one embodiment, patterned layer 34 may include a single instance of a pattern geometry 36 that corresponds with a resistor and a single instance of a pattern geometry 36 that corresponds with a capacitor.

As discussed below with reference to FIG. 3B, patterned layer 34, which may include pattern geometry 36, may be formed from any suitable opaque metal material or partially transmissive material. Patterned layer 34 may be formed on a transparent substrate 38 in a first region 40 corresponding with first region 20 of die 12.

FIG. 3B illustrates a cross-sectional view of a photomask assembly 50 that includes first photomask 30 in accordance with a particular embodiment. Photomask assembly 50 may include a pellicle assembly 52 mounted on first photomask 30. Substrate 38, patterned layer 34, a zero degree phase shift window (PSW), a ninety degree PSW and a 180 degree PSW may form first photomask 30, otherwise known as a mask or reticle, that may have a variety of sizes and shapes, including but not limited to round, rectangular, or square. For example, the example first photomask 30 shown in FIG. 3A has a rectangular shape. First photomask 30 may also be any of a variety of photomask types, including, but not limited to, a one-time master, a five-inch reticle, a six-inch reticle, a nine-inch reticle or any other appropriately sized reticle that may be used to project an image of a circuit pattern onto a semiconductor wafer. First photomask 30 may further be a binary mask, a phase shift mask (PSM) (e.g., an alternating aperture phase shift mask, also known as a Levenson type mask), an optical proximity correction (OPC) mask, or any other type of mask suitable for use in a lithography system.

First photomask 30 may include patterned layer 34 formed on a top surface 56 of substrate 38 that, when exposed to electromagnetic energy in a lithography system, projects a pattern onto a surface of semiconductor wafer 10. As discussed above, patterned layer 34 may include pattern geometry 36 that may correspond with, and may be used to form, each of multiple instances of a particular critical-geometry integrated circuit component 24 in first region 20 of die 12. In some embodiments, substrate 38 may be a transparent material such as quartz, synthetic quartz, fused silica, magnesium fluoride (MgF₂), calcium fluoride (CaF₂), or any other suitable material that transmits at least 75% of incident light having a wavelength between approximately 10 nanometers (nm) and approximately 450 nm. In other embodiments, substrate 38 may be a reflective material such as silicon or any other suitable material that reflects greater than approximately 50% of incident light having a wavelength between approximately 10 nm and 450 nm.

In some embodiments, patterned layer 34 may be a metal material such as chrome, chromium nitride, a metallic oxy-carbo-nitride (e.g., MOCN, where M is selected from the group consisting of chromium, cobalt, iron, zinc, molybdenum, niobium, tantalum, titanium, tungsten, aluminum, magnesium, and silicon), or any other suitable material that absorbs electromagnetic energy with wavelengths in the ultraviolet (UV) range, deep ultraviolet (DUV) range, vacuum ultraviolet (VUV) range and extreme ultraviolet range (EUV). In other embodiments, patterned layer 34 may be a partially transmissive material, such as molybdenum silicide (MoSi), which has a transmissivity of approximately 1% to approximately 30% in the UV, DUV, VUV and EUV ranges.

Frame 60 and pellicle film 62 may form pellicle assembly 52. In some embodiments, frame 60 may be formed of anodized aluminum, although it could alternatively be formed of stainless steel, plastic or other suitable materials that do not degrade or outgas when exposed to electromagnetic energy within a lithography system. In some embodiments, pellicle film 62 may be a thin film membrane formed of a material such as nitrocellulose, fluoropolymer, cellulose acetate, an amorphous such as TEFLON® AF manufactured by E. I. du Pont de Nemours and Company or CYTOP® manufactured by Asahi Glass, or another suitable film that is transparent to wavelengths in the UV, DUV, EUV and/or VUV ranges. Pellicle film 62 may be prepared by a conventional technique such as spin casting, for example.

Pellicle film 62 may protect first photomask 30 from contaminants, such as dust particles, by ensuring that the contaminants remain a defined distance away from first photomask 30. This may be especially important in a lithography system. During a lithography process, photomask assembly 50 may be exposed to electromagnetic energy produced by a radiant energy source within the lithography system. The electromagnetic energy may include light of various wavelengths such as wavelengths approximately between the I-line and G-line of a Mercury arc lamp, or DUV, VUV or EUV light. In operation, pellicle film 62 may be designed to allow a large percentage of the electromagnetic energy to pass through it. Contaminants collected on pellicle film 62 are likely out of focus at the surface of the wafer being processed and, therefore, the exposed image on the wafer is likely clear. Pellicle film 62 formed in accordance with the teachings of the present invention may be satisfactorily used with all types of electromagnetic energy and is not limited to light waves as described in this application.

First photomask 30 may be formed from a photomask blank using a standard lithography process. In a lithography process, a mask pattern file that includes data for patterned layer 34 may be generated from a mask layout file. In one embodiment, the mask layout file may include polygons that represent transistors (and/or various other integrated circuit components) and electrical connections for an integrated circuit. The polygons in the mask layout file may further represent different layers of the integrated circuit when it is fabricated on a semiconductor wafer. For example, a transistor may be formed on a semiconductor wafer with a diffusion layer and a polysilicon layer. The mask layout file, therefore, may include one or more polygons drawn on the diffusion layer and one or more polygons drawn on the polysilicon layer. The polygons for each layer may be converted into a mask pattern file that represents one layer of the integrated circuit. Each mask pattern file may be used to generate a photomask for the specific layer. In some embodiments, the mask pattern file may include more than one layer of the integrated circuit such that a photomask may be used to image features from more than one layer onto the surface of a semiconductor wafer.

The desired pattern may be imaged into a resist layer of the photomask blank using a laser, electron beam, X-ray lithography system, or other suitable device or system. In one embodiment, a laser lithography system may use an Argon-Ion laser that emits light having a wavelength of approximately 364 nanometers (nm). In alternative embodiments, the laser lithography system may use lasers emitting light at wavelengths from approximately 150 nm to approximately 300 nm. First photomask 30 may be fabricated by developing and etching exposed areas of the resist layer to create a pattern, etching the portions of patterned layer 34 not covered by resist, and removing the undeveloped resist to create patterned layer 34 over substrate 38.

It should be understood that in some embodiments, patterned layer 34 may include more than one pattern geometry 36. For example, patterned layer 34 may include a first pattern geometry 36 corresponding to a resistor and a second pattern geometry 36 corresponding to a capacitor. Multiple instances of the resistor and capacitor may then be formed on die 12 by aligning the first and second pattern geometries 36 at different locations on die 12. In addition, multiple photomasks similar to first photomask 30 may be used to form different critical-geometry integrated circuit components on a die 12. For example, one photomask having a pattern geometry 36 corresponding to a resistor of a first size may be used to form multiple instances, or copies, of the first-sized resistor on a die 12, and another photomask having a pattern geometry 36 corresponding to a resistor of a second size may be used to form multiple instances, or copies, of the second-sized resistor on the same die 12.

FIG. 4A illustrates a top view of an example second photomask 32 that may be used to form one or more non-critical-geometry IC components 28 in second region 22 of die 12 in accordance with one embodiment of the invention. As discussed below, in some embodiments, such one or more non-critical-geometry IC components 28 may be formed by performing a single photolithographic imaging process using second photomask 32.

As shown in FIG. 4A, second photomask 32 may include a patterned layer 74 that includes one or more pattern geometries 76 that correspond to one or more non-critical-geometry IC components 28 to be formed in second region 22 of die 12, such as various resistors, capacitors, metal lines, vias and/or interconnects, for example. As discussed below with reference to FIG. 4B, patterned layer 74, which includes pattern geometries 76, may be formed from any suitable opaque metal material or partially transmissive material. Patterned layer 74 may be formed on a transparent substrate 78 in a second region 80 corresponding with second region 22 of die 12. In some embodiments, second region 80 may partially or completely exclude first region 40.

FIG. 4B illustrates a cross-sectional view of photomask assembly 84 that includes second photomask 32 in accordance with one embodiment. Photomask assembly 84 may include pellicle assembly 86 mounted on second photomask 32. Substrate 78, patterned layer 74, a zero degree phase shift window (PSW), a ninety degree PSW and a 180 degree PSW may form second photomask 32, otherwise known as a mask or reticle, that may have a variety of sizes and shapes, including but not limited to round, rectangular, or square. For example, the example second photomask 32 shown in FIG. 4A has a rectangular shape. Second photomask 32 may also be any of a variety of photomask types, including, but not limited to, a one-time master, a five-inch reticle, a six-inch reticle, a nine-inch reticle or any other appropriately sized reticle that may be used to project an image of a circuit pattern onto a semiconductor wafer, for example. Second photomask 32 may further be a binary mask, a phase shift mask (PSM) (e.g., an alternating aperture phase shift mask, also known as a Levenson type mask), an optical proximity correction (OPC) mask or any other type of mask suitable for use in a lithography system.

Second photomask 32 may include patterned layer 74 formed on top surface 88 of substrate 78 that, when exposed to electromagnetic energy in a lithography system, projects a pattern onto a surface of semiconductor wafer 10. As discussed above, patterned layer 74 may include one or more pattern geometries 76 that may corresponds with and may be used to form, one or more non-critical-geometry IC components 28 in second region 22 of die 12. In some embodiments, substrate 78 may be a transparent material such as quartz, synthetic quartz, fused silica, magnesium fluoride (MgF₂), calcium fluoride (CaF₂), or any other suitable material that transmits at least 75% of incident light having a wavelength between approximately 10 nanometers (nm) and approximately 450 nm. In other embodiments, substrate 78 may be a reflective material such as silicon or any other suitable material that reflects greater than approximately 50% of incident light having a wavelength between approximately 10 nm and 450 nm.

In some embodiments, patterned layer 74 may be a metal material such as chrome, chromium nitride, a metallic oxy-carbo-nitride (e.g., MOCN, where M is selected from the group consisting of chromium, cobalt, iron, zinc, molybdenum, niobium, tantalum, titanium, tungsten, aluminum, magnesium, and silicon), or any other suitable material that absorbs electromagnetic energy with wavelengths in the ultraviolet (UV) range, deep ultraviolet (DUV) range, vacuum ultraviolet (VUV) range and extreme ultraviolet range (EUV). In other embodiments, patterned layer 74 may be a partially transmissive material, such as molybdenum silicide (MoSi), which has a transmissivity of approximately 1% to approximately 30% in the UV, DUV, VUV and EUV ranges.

Frame 90 and pellicle film 92 may form pellicle assembly 86. Frame 90 may be formed of anodized aluminum, although it could alternatively be formed of stainless steel, plastic or other suitable materials that do not degrade or outgas when exposed to electromagnetic energy within a lithography system. In some embodiments, pellicle film 92 may be a thin film membrane formed of a material such as nitrocellulose, cellulose acetate, an amorphous fluoropolymer, such as TEFLON® AF manufactured by E. I. du Pont de Nemours and Company or CYTOP® manufactured by Asahi Glass, or another suitable film that is transparent to wavelengths in the UV, DUV, EUV and/or VUV ranges. Pellicle film 92 may be prepared by a conventional technique such as spin casting.

Pellicle film 92 may protect second photomask 32 from contaminants, such as dust particles, by ensuring that the contaminants remain a defined distance away from second photomask 32. This may be especially important in a lithography system. During a lithography process, photomask assembly 84 may be exposed to electromagnetic energy produced by a radiant energy source within the lithography system. The electromagnetic energy may include light of various wavelengths, such as wavelengths approximately between the I-line and G-line of a Mercury arc lamp, or DUV, VUV or EUV light. In operation, pellicle film 92 may be designed to allow a large percentage of the electromagnetic energy to pass through it. Contaminants collected on pellicle film 92 are likely out of focus at the surface of the wafer being processed and, therefore, the exposed image on the wafer is likely clear. Pellicle film 92 formed in accordance with the teachings of the present invention may be satisfactorily used with all types of electromagnetic energy and is not limited to light waves as described in this application.

Second photomask 32 may be formed from a photomask blank using a standard lithography process. For example, a mask pattern file that includes data for patterned layer 74 may be generated from a mask layout file, which may include polygons that represent transistors (and/or various other integrated circuit components) and electrical connections for an integrated circuit. The polygons in the mask layout file may further represent different layers of the integrated circuit when it is fabricated on a semiconductor wafer. For example, a transistor may be formed on a semiconductor wafer with a diffusion layer and a polysilicon layer. The mask layout file, therefore, may include one or more polygons drawn on the diffusion layer and one or more polygons drawn on the polysilicon layer. The polygons for each layer may be converted into a mask pattern file that represents one layer of the integrated circuit. Each mask pattern file may be used to generate a photomask for the specific layer. In some embodiments, the mask pattern file may include more than one layer of the integrated circuit such that a photomask may be used to image features from more than one layer onto the surface of a semiconductor wafer.

The desired pattern may be imaged into a resist layer of the photomask blank using a laser, electron beam, X-ray lithography system, or other suitable device or system, such as discussed above, for example. Second photomask 32 may be fabricated by developing and etching exposed areas of the resist layer to create a pattern, etching the portions of patterned layer 74 not covered by resist, and removing the undeveloped resist to create patterned layer 74 over substrate 78.

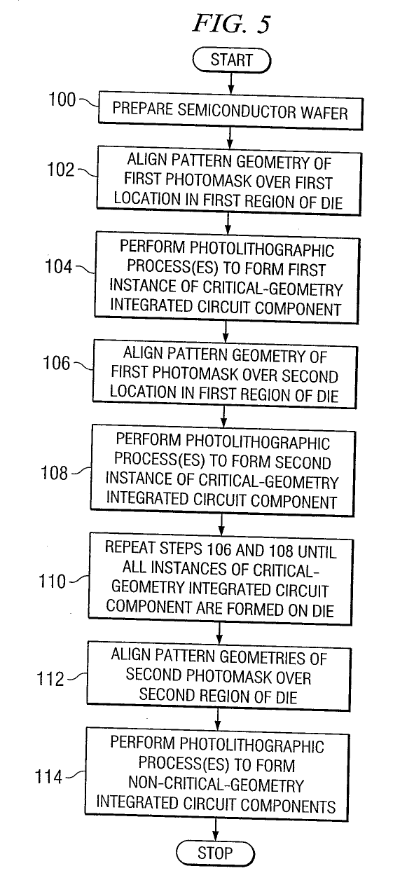

FIG. 5 illustrates a flow chart of a method for forming critical-geometry IC components 24 and non-critical-geometry IC components 28 in first and second regions 20 and 22 using first and second photomasks 30 and 32, respectively, in accordance with one embodiment of the invention.

At step 100, semiconductor wafer 10 may be prepared such that critical-geometry IC components 24 and non-critical-geometry IC components 28 may be formed in first and second regions 20 and 22 of die 12, respectively. This may involved any one or more suitable integrated circuit fabrication processes or techniques known in the art.

At step 102, first photomask 30 may be aligned over die 12 such that pattern geometry 36 of first photomask 30 is aligned over a first location in first region 20 in which a first instance, shown in FIG. 2 as component 24a, of a critical-geometry integrated circuit component 24 is to be formed. At step 104, a set of one or more photolithographic processes may be performed in order to transfer pattern geometry 36 onto die 12 to form first instance 24a of the critical-geometry integrated circuit component 24.

At step 106, first photomask 30 may be re-aligned over die 12 such that pattern geometry 36 of first photomask 30 is now aligned over a second location in first region 20 in which a second instance, shown in FIG. 2 as component 24b, of the critical-geometry integrated circuit component 24 is to be formed. At step 108, a set of one or more photolithographic processes may be performed in order to transfer pattern geometry 36 onto die 12 to form second instance 24b of the critical-geometry integrated circuit component 24.

At step 110, steps 106 and 108 may be repeated until all of the desired instances of the critical-geometry integrated circuit component 24 are formed in first region 20 of die 12. In this manner, the single pattern geometry 36 on photomask 30 may be used to form multiple instances, or copies, of a particular corresponding integrated circuit component (such as a resistor or capacitor, for example).

At step 112, second photomask 32 may be aligned over die 12 such that pattern geometries 76 of second photomask 32 are aligned over locations in second region 22 of die 12 in which one or more non-critical-geometry IC components 28 are to be formed. At step 114, a set of one or more photolithographic processes may be performed in order to transfer pattern geometries 76 onto die 12 to form one or more desired non-critical-geometry IC components 28 in second region 22 of die 12.

It should be understood that in alternative embodiments, of the present invention contemplates using methods with additional steps, fewer steps, different steps, or steps in different sequential order so long as the steps remain appropriate for forming critical-geometry integrated circuit components 24 having at least substantially identical geometries.

According to the method of FIG. 5, critical-geometry IC components 24 and non-critical-geometry IC components 28 may be formed in first and second regions 20 and 22 using first and second photomasks 30 and 32, respectively. Because the critical-geometry IC components 24 may be formed by projecting the same pattern geometry 36 onto different locations of die 12 (within first region 20), geometric differences between individual critical-geometry IC components 24 may be reduced as compared with prior techniques for forming such components. In particular, geometric differences in integrated circuit components that are caused by geometric differences between multiple instances of a pattern geometry in a patterned layer of a photomask may be reduced or eliminated by using the techniques discussed herein. As a result, the number of repairs (such as laser ablation repairs, for example) required to correct critical-geometry integrated circuit components on the wafer having “non-matching,” inaccurate or otherwise undesirable geometries may be reduced or eliminated, which may reduce cycle time, increase throughput, and/or reduce costs.

Although the present invention has been described with respect to a specific preferred embodiment thereof, various changes and modifications may be suggested to one skilled in the art and it is intended that the present invention encompass such changes and modifications fall within the scope of the appended claims.

What is claimed is:

1. A method of forming integrated circuit components, comprising:
forming a first photomask including a first mask component having a first geometry corresponding to a first type of integrated circuit component;
performing a first lithography process to transfer the first geometry of the first mask component of the first photomask to a first location on a first die on a semiconductor wafer to form a first integrated circuit component of the first type of integrated circuit component on the first die; and
performing a second lithography process to transfer the first geometry of the first mask component of the first photomask to a second location on the first die on the semiconductor wafer to form a second integrated circuit component of the first type of integrated circuit component on the first die.

2. The method of claim 1, further comprising:
the first and second integrated circuit components located in an integrated circuit device; and
the first and second integrated circuit components related such that the performance of the integrated circuit device is based at least on an electrical characteristic of the first integrated circuit component being at least substantially identical to the electrical characteristic of the second integrated circuit component.

3. The method of claim 1, wherein:
the first type of integrated circuit component comprises a resistor;
the first integrated circuit component comprises a first resistor;
the second integrated circuit component comprises a second resistor;
the first and second resistors are located in an integrated circuit device; and
the first and second resistors are related such that the performance of the integrated circuit device is based at least on the resistance of the first resistor being at least substantially identical to the resistance of the second resistor.

4. The method of claim 1, wherein:
the first type of integrated circuit component comprises a capacitor;
the first integrated circuit component comprises a first capacitor;
the second integrated circuit component comprises a second capacitor;
the first and second capacitors are located in an integrated circuit device; and
the first and second capacitors are related such that the performance of the integrated circuit device is based at least on the capacitance of the first capacitor being at least substantially identical to the capacitance of the second resistor.

5. The method of claim 1, further comprising performing one or more additional lithography processes to transfer the first geometry of the first component of the first photomask to each of one or more additional locations of the semiconductor wafer to form one or more additional integrated circuit components of the first type of integrated circuit component.

6. The method of claim 1, wherein:
performing the first lithography process comprises aligning the first photomask at a first position relative to the first die; and
performing the second lithography process comprises aligning the first photomask at a second position relative to the first die.

7. The method of claim 1, further comprising performing one or more additional lithography processes using a second photomask to form one or more additional integrated circuit components on the first die.

8. The method of claim 7, wherein the one or more additional integrated circuit components include at least one integrated circuit components of a second type of integrated circuit component.

9. The method of claim 7, wherein:
the first type of integrated circuit components comprise integrated circuit components having critical geometries; and
the one or more additional type integrated circuit components comprise a second type of integrated circuit component, the second type of integrated circuit components comprising integrated circuit components having non-critical geometries.

10. The method of claim 7, further comprises:
the first mask component formed in a first region of the first photomask corresponding with a first region of the first die, the first and second locations on the first die being located in the first region of the first die;
the one or more additional integrated circuit components located in a second region of the first die; and
the second photomask including one or more second mask components that are used to form the one or more additional integrated circuit components in the second region of the first die.

11. The method of claim 10, wherein the first region of the first die is distinct from the second region of the first die.

12. The method of claim 1, further comprising:
forming a second photomask including a plurality of second mask components, at least one of the plurality of second mask components having a second geometry corresponding to a second type of integrated circuit component; and
performing a single lithography process using the second photomask to form a plurality of additional integrated circuit components in the first die.

13. An integrated circuit device comprising:
a first integrated circuit component of a first type of integrated circuit component, the first integrated circuit component located at a first location on a first die on a semiconductor wafer and formed at least by:
forming a first photomask including a first mask component having a first geometry corresponding to a first type of integrated circuit component; and
performing a first lithography process to transfer the first geometry of the first mask component of the first photomask to the first location on the first die to form a first integrated circuit component; and
a second integrated circuit component of the first type of integrated circuit component, the second integrated circuit component located at a second location on the first die on the semiconductor wafer and formed at least by:
performing a second lithography process to transfer the first geometry of the first mask component of the first photomask to the second location on the first die to form a second integrated circuit component.

14. The integrated circuit device of claim 13, further comprising:
the first and second integrated circuit components related such that the performance of the integrated circuit device is based at least on an electrical characteristic of the first integrated circuit component being at least substantially identical to the electrical characteristic of the second integrated circuit component.

15. The integrated circuit device of claim 13, wherein:
the first type of integrated circuit component comprises a resistor;
the first integrated circuit component comprises a first resistor;
the second integrated circuit component comprises a second resistor; and
the first and second resistors are related such that the performance of the integrated circuit device is based at least on the resistance of the first resistor being at least substantially identical to the resistance of the second resistor.

16. The integrated circuit device of claim 13, wherein:
the first type of integrated circuit component comprises a capacitor;
the first integrated circuit component comprises a first capacitor;
the second integrated circuit component comprises a second capacitor; and
the first and second capacitors are related such that the performance of the integrated circuit device is based at least on the capacitance of the first capacitor being at least substantially identical to the capacitance of the second resistor.

17. The integrated circuit device of claim 13, further comprising one or more additional integrated circuit components of the first type of integrated circuit component located at one or more additional location on the first die on the semiconductor wafer and formed at least by performing one or more additional lithography processes to transfer the first geometry of the first component of the first photomask to each of the one or more additional locations of the semiconductor wafer.

18. The integrated circuit device of claim 13, wherein:
performing the first lithography comprises aligning the first photomask at a first position relative to the first die; and
performing the second lithography process comprises aligning the first photomask at a second position relative to the first die.

19. The integrated circuit device of claim 13, further comprising:
one or more additional integrated circuit components of a second type of integrated circuit component located at one or more additional location on the first die on the semiconductor wafer, the one or more additional integrated circuit components being formed at least by performing one or more additional lithography processes using a second photomask.

20. The integrated circuit device of claim 19, wherein:
the first type of integrated circuit components comprise integrated circuit components having critical geometries; and
the one or more additional integrated circuit components comprise a second type of integrated circuit component, the second type of integrated circuit components comprising integrated circuit components having non-critical geometries

21. The integrated circuit device of claim 19, further comprising:
the first mask component formed in a first region of the first photomask corresponding with a first region of the first die, the first and second locations on the first die being located in the first region of the first die;
the one or more additional integrated circuit components located in a second region of the first die; and
the second photomask including one or more second mask components that are used to form the one or more additional integrated circuit components in the second region of the first die.

22. The integrated circuit device of claim 21, wherein the first region of the first die is distinct from the second region of the first die.

23. The integrated circuit device of claim 13, further comprising a plurality of additional integrated circuit components located at one or more additional location on the first die on the semiconductor wafer, the plurality of additional integrated circuit components including at least one of a second type of integrated circuit component and being formed at least by:
forming a second photomask including a plurality of second mask components, at least one of the plurality of second mask components having a second geometry corresponding to the second type of integrated circuit component; and
performing a single lithography process using the second photomask to form the plurality of additional integrated circuit components in the first die.
